(19) United States
(12) Patent Application Publication
(10) Pub. No.: US 2025/0150040 A1
(43) Pub. Date: May 8, 2025

(54) DIGITAL PRE-DISTORTER FOR NON-LINEAR ELECTRONIC DEVICES

(71) Applicant: Telefonaktiebolaget LM Ericsson (publ), Stockholm (SE)

(72) Inventors: Ang Feng, Solna (SE); Sener Dikmese, Sundbyberg (SE); Hao Gao, Beijing (CN)

(21) Appl. No.: 18/730,458

(22) PCT Filed: Jan. 20, 2022
(86) PCT No.: PCT/CN2022/072875

§ 371 Date: Jul. 19, 2024

(51) Int. Cl. H03F 1/32

(52) U.S. Cl. CPC H03F 1/3241

(57) ABSTRACT

There is provided mechanisms for operating a DPD for a non-linear electronic device. A method is performed by a DPD controller. The method comprises receiving an input signal destined to be input to the non-linear electronic device. The method comprises selecting a basis function that represent non-linear input-output characteristics of the non-linear electronic device. The basis function is defined by kernels of a pruned Volterra series, and comprises higher-than-order-1 polynomial terms, polynomial cross-terms, memory cross-terms, and common tap delays shared by all polynomial terms. The method comprises obtaining an output signal by subjecting the input signal to a linearization function defined by the basis function. The method comprises providing the output signal as input to the non-linear electronic device.

### TECHNICAL FIELD

Embodiments presented herein relate to a method, a digital pre-distorter (DPD) controller, a computer program, and a computer program product for operating a DPD for a non-linear electronic device.

### BACKGROUND

Some electronic devices exhibit non-linear input-output characteristics and are therefore referred to as non-linear electronic devices. Non-linear electronic devices can be found in many types of electronic equipment, such as transmitters, receivers, transceivers, signal converters, and the like. Non-limiting examples of non-linear electronic devices are radio frequency (RF) amplifiers, power amplifiers (PAS), low-noise amplifiers (LNAs), etc.

In some scenarios the non-linear behaviour caused by the non-linear input-output characteristics is undesired and efforts are therefore made to make the non-linear input-output characteristics linear, and thus to linearize the non-linear electronic device. One way to linearize the non-linear electronic device is to connect the output of a linearizer device to the input of the non-linear electronic device such that the input to the non-linear electronic device is fed, and processed by, the linearizer device.

A DPD is an example of a linearizer device and can thus be used to mitigate the spectrum regrowth for non-linear electronic devices. Typically, the DPD comprises an actuator, or pre-distorter, placed in the forward path to inverse the non-linear behavior of the non-linear electronic device, and an estimator, or adaptation, in a feedback path to determine the coefficients for the forward path. An observation receiver can be deployed in the feedback path to observe the output from the non-linear electronic device.

Typically, DPD is composed of a predistortion block to modify the transmitting signal before the non-linear electronic device, and an adaptation block to provide coefficients used by the predistortion block. The predistortion block uses a basis function (BF) that aims at reversing the non-linear behavior of the non-linear electronic device. Different types of techniques, such as look-up-tables (LUTs), Volterra series (VS), general memory polynomials (GMPs), dynamic deviation reduction (DDRs), neural networks (NNs), etc. have been proposed to determine BFs. The performance of the DPD increases with the number of terms in the BF. However, the computational complexity also increases with the number of terms in the BF. It could therefore be cumbersome to select a BF with both high performance and low complexity.

Using LUTs is a favorable approach in implementations due to its lower computational complexity compared to the other mentioned techniques. Meanwhile, LUTs can avoid global dependency on local effects. This makes LUTs suitable for strongly amplitude-dependent nonlinearity. However, it can be complicated to perform an accurate analysis of the performance of LUTs. This also implies that a comparable large amount of time is required for tuning the performance. For instance, the tap delays for multiple LUTs are difficult to be found in short time.

GMP and DDR are two most widely used model that are pruned from VS. Since polynomials are calculated in the predistortion block, GMP and DDR usually have higher complexity compared to LUTs. Polynomials are good at compensation of the whole operation region of the non-linear electronic device and may have the benefit to avoid catastrophic deterioration due to local unexpected behavior. The analysis of the performance of polynomial based DPDs is comparatively simpler than for LUTs. Hence, in most of the studies in academia polynomial based DPDs are often used compared to LUT based DPDs for emphasizing their advantages.

No successful deployment of NN based DPDs (as well as other machine learning (ML) based DPDs) has thus far been shown. This is mainly due to the required computational computation that currently is prohibited in real-life devices where low power consumption and stringent latency are required.

Further, adaptation of the coefficients as performed in the adaptation block in the DPD could have the capability to approach the optimal results and track the dynamic behavior of the non-linear electronic device in an efficient way. Different types of adaptation algorithms, such as least mean squares (LMS), recursive least squares (RLS), conjugate gradient (CG), stochastic gradient descent (SGD), quasi-second-order gradient, etc. have been proposed to be utilized for this purpose in the adaptation block. Each adaptation algorithm has its own advantages and disadvantages and due to that it can be difficult to decide which one is better than the other ones.

The adaptation algorithm is basically the same regardless if any of LUTs, GMPs or DDRs are used in the predistortion block. Any gradient based adaptation algorithm can be used for any of these techniques, with a common tradeoff between performance and complexity. In the adaptation for LUTs, the BF is commonly represented by a large-scale sparse matrix. The sparsity should be leveraged to simplify the calculations. Otherwise, running the adaptation algorithm may require prohibitive computational complexity. The sparsity might, for example, be utilized when calculating the Jacobian matrix in the CG algorithm for the first-order gradient. For the second-order gradient, the Hessian matrix can also be calculated in the CG algorithm. For the quasi-second-order gradient, the Hessian matrix can be approximated. On the other hand, the BF when using GMP or DDR is a relatively small-scale dense matrix, but it might be ill-condition. The adaptation algorithm utilized for such a BF should thus consider the impact of ill-conditioning. Otherwise, the stability of the adaptation algorithm may be problematic during calculation. Some examples to solve ill-conditioned equations involve the use of regularization terms or Gram-Schmidt orthogonalization.

On the one hand, LUT based DPDs outperforms polynomial based DPDs in terms of both less computational complexity and reasonably good performance. On the other hand, polynomial based DPDs might be considered better than LUT based DPDs in terms of straightforward theoretical performance analysis and parameter tuning such as for suitable data delays and address delays.

In view of the above, there is thus still a need for an improved DPD.

### SUMMARY

An object of embodiments herein is to provide a DPD that does not suffer from the issues disclosed above, or at least where the above disclosed issues have been mitigated or reduced.

According to a first aspect there is presented a method for operating a DPD for a non-linear electronic device. The method is performed by a DPD controller. The method comprises receiving an input signal destined to be input to the non-linear electronic device. The method comprises selecting a basis function that represent non-linear input-output characteristics of the non-linear electronic device. The basis function is defined by kernels of a pruned Volterra series, and comprises higher-than-order-1 polynomial terms, polynomial cross-terms, memory cross-terms, and common tap delays shared by all polynomial terms. The method comprises obtaining an output signal by subjecting the input signal to a linearization function defined by the basis function. The method comprises providing the output signal as input to the non-linear electronic device.

According to a second aspect there is presented a DPD controller for operating a DPD for a non-linear electronic device. The DPD controller comprises processing circuitry. The processing circuitry is configured to cause the DPD controller to receive an input signal destined to be input to the non-linear electronic device. The processing circuitry is configured to cause the DPD controller to select a basis function that represent non-linear input-output characteristics of the non-linear electronic device. The basis function is defined by kernels of a pruned Volterra series, and comprises higher-than-order-1 polynomial terms, polynomial cross-terms, memory cross-terms, and common tap delays shared by all polynomial terms. The processing circuitry is configured to cause the DPD controller to obtain an output signal by subjecting the input signal to a linearization function defined by the basis function. The processing circuitry is configured to cause the DPD controller to provide the output signal as input to the non-linear electronic device.

According to a third aspect there is presented a DPD controller for operating a DPD for a non-linear electronic device. The DPD controller comprises a receive module (210a) configured to receive an input signal destined to be input to the non-linear electronic device. The DPD controller comprises a select module configured to select a basis function that represent non-linear input-output characteristics of the non-linear electronic device. The basis function is defined by kernels of a pruned Volterra series, and comprises higher-than-order-1 polynomial terms, polynomial cross-terms, memory cross-terms, and common tap delays shared by all polynomial terms. The DPD controller comprises an obtain module configured to obtain an output signal by subjecting the input signal to a linearization function defined by the basis function. The DPD controller comprises a provide module configured to provide the output signal as input to the non-linear electronic device.

According to a fourth aspect there is presented a computer program for operating a DPD for a non-linear electronic device, the computer program comprising computer program code which, when run on a DPD controller, causes the DPD controller to perform a method according to the first aspect.

According to a fifth aspect there is presented a computer program product comprising a computer program according to the fourth aspect and a computer readable storage medium on which the computer program is stored. The computer readable storage medium could be a non-transitory computer readable storage medium.

Advantageously, the disclosed DPD does not suffer from the issues noted above.

Advantageously, the disclosed DPD has outstanding performance for linearization of non-linear electronic devices such as wideband power amplifiers.

Advantageously, the predistortion block of the disclosed DPD can be implemented with a low implementation cost.

Advantageously, these aspects enable the tap delays to be selected in a computationally and memory efficient manner.

Advantageously, the adaptation block of the disclosed DPD can be implemented with a low implementation cost but still yielding high performance.

Advantageously, these aspects enable the DPD to have a low power consumption and thus a high energy efficiency.

Other objectives, features and advantages of the enclosed embodiments will be apparent from the following detailed disclosure, from the attached dependent claims as well as from the drawings.

Generally, all terms used in the claims are to be interpreted according to their ordinary meaning in the technical field, unless explicitly defined otherwise herein. All references to “a/an/the element, apparatus, component, means, module, step, etc.” are to be interpreted openly as referring to at least one instance of the element, apparatus, component, means, module, step, etc., unless explicitly stated otherwise.

The steps of any method disclosed herein do not have to be performed in the exact order disclosed, unless explicitly stated.

### BRIEF DESCRIPTION OF THE DRAWINGS

The inventive concept is now described, by way of example, with reference to the accompanying drawings, in which:

FIG. 1 is a schematic diagram illustrating a DPD according to an embodiment;

FIG. 2 is a flowchart of methods according to embodiments;

FIGS. 3 and 4 are schematic diagrams of a pre-distortion block according to embodiments;

FIGS. 5, 6, and 7 show simulation results according to embodiments;

FIG. 8 is a schematic diagram showing functional units of a DPD controller according to an embodiment;

FIG. 9 is a schematic diagram showing functional modules of a DPD controller according to an embodiment; and

FIG. 10 shows one example of a computer program product comprising computer readable storage medium according to an embodiment.

### DETAILED DESCRIPTION

The inventive concept will now be described more fully hereinafter with reference to the accompanying drawings, in which certain embodiments of the inventive concept are shown. This inventive concept may, however, be embodied in many different forms and should not be construed as limited to the embodiments set forth herein; rather, these embodiments are provided by way of example so that this disclosure will be thorough and complete, and will fully convey the scope of the inventive concept to those skilled in the art. Like numbers refer to like elements throughout the description. Any step or feature illustrated by dashed lines should be regarded as optional.

The embodiments disclosed herein relate to mechanisms for operating a DPD for a non-linear electronic device. In order to obtain such mechanisms, there is provided a DPD controller, a method performed by the DPD controller, a computer program product comprising code, for example in the form of a computer program, that when run on a DPD controller, causes the DPD controller to perform the method.

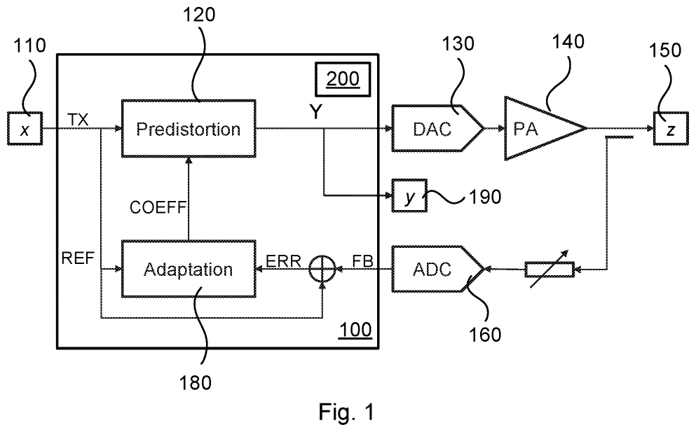

FIG. 1 shows an example of a DPD 100 based on a so-called direct-learning architecture (DLA). The DPD 100 is controlled by a DPD controller 200. The DPD 100 is configured to, from a signal source 110, receive an input signal “X” destined to be input to a non-linear electronic device 140 in terms of a PA 140. In some non-limiting examples, the signal source 110 is a signal modulating entity. The signal modulating entity could be a data modulating device e.g. operating at baseband and which is configured to process signals after being channel filtered and/or limited to some amplitude crest factor.

The input signal is modified in a predistortion block 120 using a set of BFs. The predistortion block 120 has the capability to revert the behaviour of the PA 140. The modification performed by the predistortion block 120 results in an output signal “Y”. The DPD 100 is operatively connected to the non-linear electronic device via a digital-to-analog converter (DAC) 130 in the forward path and an analog-to-digital converter (ADC) 160 in the feedback path. An adaptation block 180 calculates a coefficient (“COEFF”) used in the predistortion block 120 based on the input signal to the DPD 100 as well as an error signal (“ERR”) based on a difference between the input signal (“REF”) to the DPD 100 and the output signal (“FB”) produced by the non-linear electronic device 140. An iterative mode can be used where the coefficient is updated gradually until the error takes a desired value.

For an input signal x(n) and an output signal y(n), a nonlinear system with memory effects can be modeled with a Volterra series as:

$$y ( n ) = {\sum }_{k = 1}^{K} {\sum }_{{m}_{k} = 0}^{M} … {\sum }_{{m}_{1} = 0}^{M} {h}_{k} ( {m}_{1} , … , {m}_{k} ) {\prod }_{l = 1}^{k} x ( n - {m}_{l} )$$

where hₖ(m₁, . . . , mₖ) denotes the Volterra kernel of a k-dimensional convolution, where K is the highest polynomial order, and where M is the memory length. Unfortunately, Volterra series have prohibitive complexity and therefore should be pruned in the practice. Which kernels should be selected generally depends on two factors: contribution and complexity. The contribution of each kernel should be evaluated case by case. The complexity also should be constraint because it is relevant to the resources and power consumption.

According to at least some of the herein disclosed embodiments, besides the common consideration mentioned above, at least the following criteria should be considered when selecting the kernels of the VS that thus forms the basis function. Firstly, higher-than-order-1 polynomial terms should be considered because they can be complexity-efficiently expressed in the form of LUTs. Secondly, polynomial cross-terms should be considered because they have major contributions on the impact of the non-linear distortion caused by the non-linear electronic device. Thirdly, memory cross-terms should be considered because they have major contributions on the impact of the memory effects caused by the non-linear electronic device. Fourthly, memory terms (i.e., tap delays) should be considered to be common for all polynomial terms.

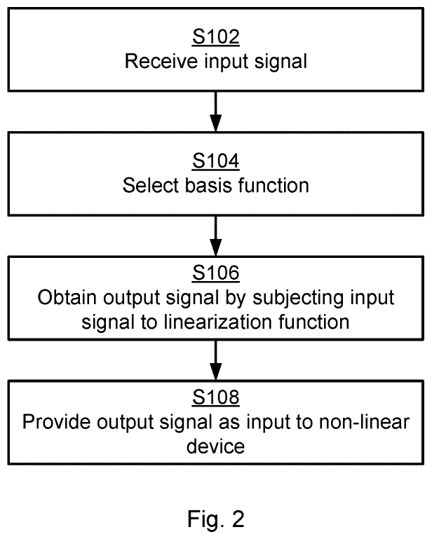

FIG. 2 is a flowchart illustrating embodiments of methods for operating a DPD 100 for a non-linear electronic device 140. The methods are performed by the DPD controller 200. The methods are advantageously provided as computer programs 1020.

S102: The DPD controller 200 receives S102 an input signal destined to be input to the non-linear electronic device 140.

S104: The DPD controller 200 selects a BF that represents non-linear input-output characteristics of the non-linear electronic device 140. The basis function is defined by kernels of a pruned VS. The BF comprises higher-than-order-1 polynomial terms, polynomial cross-terms, memory cross-terms, and common tap delays shared by all polynomial terms. Hereinafter, the higher-than-order-1 polynomial terms will be referred to as high-order polynomial terms.

S106: The DPD controller 200 obtains an output signal by subjecting the input signal to a linearization function defined by the BF.

S108: The DPD controller 200 provides the output signal as input to the non-linear electronic device 140.

Embodiments relating to further details of operating a DPD 100 for a non-linear electronic device 140 as performed by the DPD controller 200 will now be disclosed.

In some embodiments, the basis function is defined by:

$$y ( n ) = {\sum }_{i = 0}^{M} {\sum }_{f} {y}_{i , f} ( n ) , where :$$

$${y}_{i , f} ( n ) = {T}_{f} ( \vert x ( n - {A}_{i} ) \vert ) {x}^{* {q}_{2}} ( n - {A}_{i} ) {x}^{{p}_{2}} ( n - {A}_{i} ) {x}^{* {q}_{1}} ( n - {D}_{i} ) {x}^{{p}_{1}} ( n - {D}_{i} ) ,$$

where x(n) denotes the input signal, where y(n) denotes the output signal, where Aᵢ denotes address delay for filter tap i, where Dᵢ denotes data delay for the filter tap i, where q₁, q₂, p₁, and p₂ denote polynomial orders, where T_{f}(|x(n−Aᵢ)|) represents the f:th complex function with respect to |x(n−Aᵢ)|, where M is the memory length, and where x* denotes complex conjugate of x.

As follows from the above, the high-order polynomial terms are of order 2 or higher. In some examples, the high-order polynomial terms are of orders 5-7. In general terms, the polynomial orders of the high-order polynomial terms are represented by the parameters q₁, q₂, p₁, p₂. There could be different ways to select the values of these parameters and thus of the polynomial orders of the high-order polynomial terms. In some embodiments, the polynomial orders of the high-order polynomial terms depend on statistics of the input signal and/or the non-linear input-output characteristics of the non-linear electronic device 140.

The parameters and q₁, q₂, p₁, p₂ (as well as the tap delays, as represented by the parameters Aᵢ and Dᵢ) might thus be adapted according to the circumstances, depending on statistics of the input signal and/or the non-linear input-output characteristics of the non-linear electronic device 140.

With regards to the tap delays, in some embodiments, the tap delays are selected using a block orthogonal matching pursuit (block-OMP) algorithm. Further in this respect, in some examples, all tap delays are selected to have a value within a range, e.g. [−10:39]. Without loss of generality, it might be assumed that A₀=0 and D₀=0. All possible tap delays might not be included in the BF. If Aᵢ and Dᵢ are selected from a given interval, such as [−10:39], this means that M′=50·50=2500 filter taps are included in the BF. Hence, in some embodiments, the tap delays are selected from a set of available candidate tap delays, where the set of available candidate tap delays is represented by a matrix, and where the selected tap delays represent a submatrix extracted from the matrix.

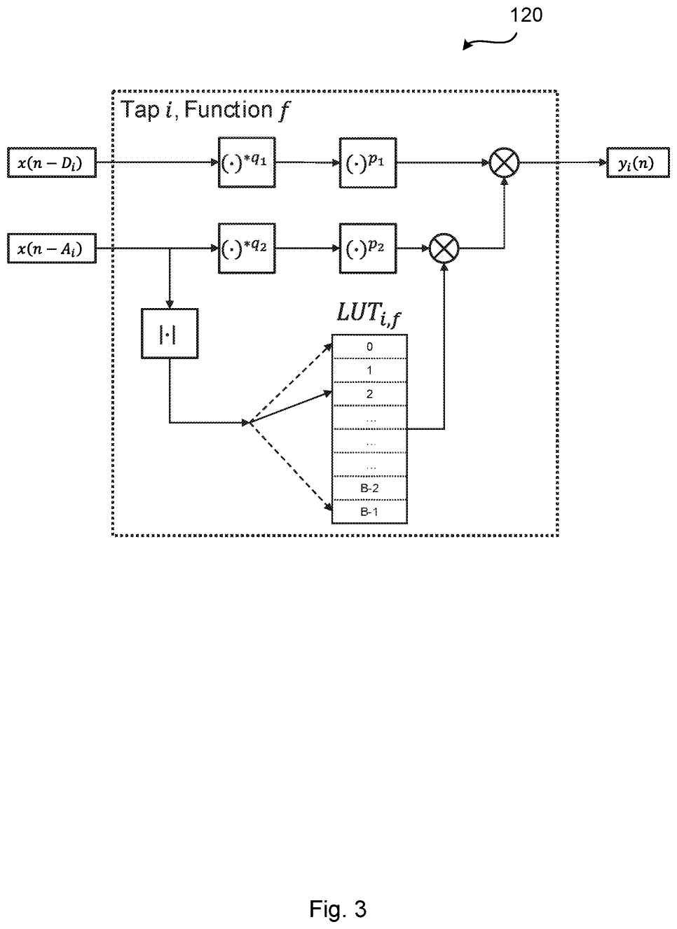

FIG. 3 illustrates a block diagram of the predistortion block 120 comprising the herein disclosed basis function. In FIG. 3, the basis function is implemented as LUT to reduce the complexity.

In the following non-limiting and illustrative example, exemplary values for q₁, q₂, p₁, p₂ as determined by physical knowledge, or by experiments performed on, a non-linear electronic device 140 represented by a given PA, as shown in Table 1. The design starts from first order terms (F₁), then adding third order terms (F₂, F₃, F₄), then adding fifth order terms (F₅, F₆, F₇, F₈, F₉), etc., until a performance that meets requirements is achieved.

TABLE 1
Exemplary values for of q₁, q₂, p₁, p₂

| | q₂ | p₂ | q₁ | p₁ |
|---|---|---|---|---|
| F₁ | 0 | 0 | 0 | 1 |
| F₂ | 0 | 2 | 1 | 0 |
| F₃ | 0 | 1 | 1 | 1 |
| F₄ | 1 | 0 | 0 | 2 |
| F₅ | 0 | 1 | 2 | 2 |
| F₆ | 1 | 0 | 1 | 3 |
| F₇ | 0 | 2 | 2 | 1 |
| F₈ | 0 | 3 | 2 | 0 |
| F₉ | 2 | 0 | 0 | 3 |

According to the example of Table 1, the BF is expressed as follows:

$$y ( n ) = {\sum }_{k = 0}^{\frac{P - 1}{2}} {\sum }_{i = 0}^{M} {g}_{1} ( k , i ) {\vert x ( n - {A}_{i} ) \vert}^{2 k} x ( n - {D}_{i} ) + {\sum }_{k = 1}^{\frac{P - 1}{2}} {\sum }_{i = 1}^{M} {g}_{2} ( k , i ) {\vert x ( n - {A}_{i} ) \vert}^{2 ( k - 1 )} {x}^{2} ( n - {A}_{i} ) {x}^{*} ( n - {D}_{i} ) + {\sum }_{k = 1}^{\frac{P - 1}{2}} {\sum }_{i = 1}^{M} {g}_{3} ( k , i ) {\vert x ( n - {A}_{i} ) \vert}^{2 ( k - 1 )} x ( n - {A}_{i} ) {\vert x ( n - {D}_{i} ) \vert}^{2} + {\sum }_{k = 1}^{\frac{P - 1}{2}} {\sum }_{i = 1}^{M} {g}_{4} ( k , i ) {\vert x ( n - {A}_{i} ) \vert}^{2 ( k - 1 )} {x}^{*} ( n - {A}_{i} ) {x}^{2} ( n - {D}_{i} ) + {\sum }_{k = 2}^{\frac{P - 1}{2}} {\sum }_{i = 1}^{M} {g}_{5} ( k , i ) {\vert x ( n - {A}_{i} ) \vert}^{2 ( k - 2 )} x ( n - {A}_{i} ) {\vert x ( n - {D}_{i} ) \vert}^{4} + {\sum }_{k = 2}^{\frac{P - 1}{2}} {\sum }_{i = 1}^{M} {g}_{6} ( k , i ) {\vert x ( n - {A}_{i} ) \vert}^{2 ( k - 2 )} {x}^{*} ( n - {A}_{i} ) {x}^{2} ( n - {D}_{i} ) {\vert x ( n - {D}_{i} ) \vert}^{2} + {\sum }_{k = 2}^{\frac{P - 1}{2}} {\sum }_{i = 1}^{M} {g}_{7} ( k , i ) {\vert x ( n - {A}_{i} ) \vert}^{2 ( k - 2 )} {x}^{2} ( n - {A}_{i} ) {x}^{*} ( n - {D}_{i} ) {\vert x ( n - {D}_{i} ) \vert}^{2} + {\sum }_{k = 2}^{\frac{P - 1}{2}} {\sum }_{i = 1}^{M} {g}_{8} ( k , i ) {\vert x ( n - {A}_{i} ) \vert}^{2 ( k - 2 )} {x}^{3} ( n - {A}_{i} ) {x}^{* 2} ( n - {D}_{i} ) + {\sum }_{k = 2}^{\frac{P - 1}{2}} {\sum }_{i = 1}^{M} {g}_{9} ( k , i ) {\vert x ( n - {A}_{i} ) \vert}^{2 ( k - 2 )} {x}^{* 2} ( n - {A}_{i} ) {x}^{3} ( n - {D}_{i} )$$

In matrix form, the behavior imposed by the DPD 100 can be expressed as a DPD model as follows:

$$y = X g$$

where y=[y(n) y(n+1) . . . y(n+N−1)]^{T} denotes the output signal. Only one processing block with N samples is shown here. X represents the BF that is constructed by the input signals as:

$$X = [ \begin{matrix}{X}_{0} ( n ) & {X}_{1} ( n ) & {X}_{2} ( n ) & … & {X}_{M} ( n ) \\ {X}_{0} ( n + 1 ) & {X}_{1} ( n + 1 ) & {X}_{2} ( n + 1 ) & … & {X}_{M} ( n + 2 ) \\ ⋮ & ⋮ & ⋮ & ⋮ & ⋮ \\ {X}_{0} ( n + N - 1 ) & {X}_{1} ( n + N - 1 ) & {X}_{2} ( n + N - 1 ) & … & {X}_{M} ( n + N - 1 )\end{matrix} ]$$

where Xᵢ denotes the BF at the i:th tap. Specifically, Xᵢ can be further expressed as:

$${X}_{i} ( n ) = \{ \begin{matrix}[ \begin{matrix}{x}_{0 , 1} ( n ) & 0 & … & 0\end{matrix} ] , & i = 0 \\ [ \begin{matrix}{x}_{i , 1} ( n ) & {x}_{i , 2} ( n ) & … & {x}_{i , 9} ( n )\end{matrix} ] , & i > 0\end{matrix}$$

Here:

$${x}_{i , 1} ( n ) = [ \begin{matrix}1 & {\vert x ( n - {A}_{i} ) \vert}^{2} & … & {\vert x ( n - {A}_{i} ) \vert}^{P - 1}\end{matrix} ] x ( n - {D}_{i} )$$

$${x}_{i , 2} ( n ) = [ \begin{matrix}1 & {\vert x ( n - {A}_{i} ) \vert}^{2} & … & {\vert x ( n - {A}_{i} ) \vert}^{P - 3}\end{matrix} ] {x}^{2} ( n - {A}_{i} ) {x}^{*} ( n - {D}_{i} )$$

$${x}_{i , 3} ( n ) = [ \begin{matrix}1 & {\vert x ( n - {A}_{i} ) \vert}^{2} & … & {\vert x ( n - {A}_{i} ) \vert}^{P - 3}\end{matrix} ] x ( n - {A}_{i} ) {\vert x ( n - {D}_{i} ) \vert}^{2}$$

$${x}_{i , 4} ( n ) = [ \begin{matrix}1 & {\vert x ( n - {A}_{i} ) \vert}^{2} & … & {\vert x ( n - {A}_{i} ) \vert}^{P - 3}\end{matrix} ] {x}^{*} ( n - {A}_{i} ) {x}^{2} ( n - {D}_{i} )$$

$${x}_{i , 5} ( n ) = [ \begin{matrix}1 & {\vert x ( n - {A}_{i} ) \vert}^{2} & … & {\vert x ( n - {A}_{i} ) \vert}^{P - 5}\end{matrix} ] x ( n - {A}_{i} ) {\vert x ( n - {D}_{i} ) \vert}^{4}$$

$${x}_{i , 6} ( n ) = [ \begin{matrix}1 & {\vert x ( n - {A}_{i} ) \vert}^{2} & … & {\vert x ( n - {A}_{i} ) \vert}^{P - 5}\end{matrix} ] {x}^{*} ( n - {A}_{i} ) {x}^{2} ( n - {D}_{i} ) {\vert x ( n - {D}_{i} ) \vert}^{2}$$

$${x}_{i , 7} ( n ) = [ \begin{matrix}1 & {\vert x ( n - {A}_{i} ) \vert}^{2} & … & {\vert x ( n - {A}_{i} ) \vert}^{P - 5}\end{matrix} ] {x}^{2} ( n - {A}_{i} ) {x}^{*} ( n - {D}_{i} ) {\vert x ( n - {D}_{i} ) \vert}^{2}$$

$${x}_{i , 8} ( n ) = [ \begin{matrix}1 & {\vert x ( n - {A}_{i} ) \vert}^{2} & … & {\vert x ( n - {A}_{i} ) \vert}^{P - 5}\end{matrix} ] {x}^{3} ( n - {A}_{i} ) {x}^{* 2} ( n - {D}_{i} )$$

$${x}_{i , 9} ( n ) = [ \begin{matrix}1 & {\vert x ( n - {A}_{i} ) \vert}^{2} & … & {\vert x ( n - {A}_{i} ) \vert}^{P - 5}\end{matrix} ] {x}^{* 2} ( n - {A}_{i} ) {x}^{3} ( n - {D}_{i} )$$

Similarly, the coefficient g can be expressed as:

$$g = {[ \begin{matrix}{g}_{0} & {g}_{1} & … & {g}_{M}\end{matrix} ]}^{T}$$

Here, the coefficient of the i:th tap are given by:

$${g}_{i} = \{ \begin{matrix}[ \begin{matrix}{g}_{0 , 1} & 0 & … & 0\end{matrix} ] , & i = 0 \\ [ \begin{matrix}{g}_{i , 1} & {g}_{i , 2} & … & {g}_{i , 9}\end{matrix} ] , & i > 0\end{matrix}$$

$${g}_{i , 1} ( n ) = [ \begin{matrix}{g}_{1} ( 0 , i ) & {g}_{1} ( 1 , i ) & … & {g}_{1} ( \frac{P - 1}{2} , i )\end{matrix} ]$$

$${g}_{i , 2} ( n ) = [ \begin{matrix}{g}_{2} ( 0 , i ) & {g}_{2} ( 1 , i ) & … & {g}_{2} ( \frac{P - 3}{2} , i )\end{matrix} ]$$

$${g}_{i , 3} ( n ) = [ \begin{matrix}{g}_{3} ( 0 , i ) & {g}_{3} ( 1 , i ) & … & {g}_{3} ( \frac{P - 3}{2} , i )\end{matrix} ]$$

$${g}_{i , 4} ( n ) = [ \begin{matrix}{g}_{4} ( 0 , i ) & {g}_{4} ( 1 , i ) & … & {g}_{4} ( \frac{P - 3}{2} , i )\end{matrix} ]$$

$${g}_{i , 5} ( n ) = [ \begin{matrix}{g}_{5} ( 0 , i ) & {g}_{5} ( 1 , i ) & … & {g}_{5} ( \frac{P - 5}{2} , i )\end{matrix} ]$$

$${g}_{i , 6} ( n ) = [ \begin{matrix}{g}_{6} ( 0 , i ) & {g}_{6} ( 1 , i ) & … & {g}_{6} ( \frac{P - 5}{2} , i )\end{matrix} ]$$

$${g}_{i , 7} ( n ) = [ \begin{matrix}{g}_{7} ( 0 , i ) & {g}_{7} ( 1 , i ) & … & {g}_{7} ( \frac{P - 5}{2} , i )\end{matrix} ]$$

$${g}_{i , 8} ( n ) = [ \begin{matrix}{g}_{8} ( 0 , i ) & {g}_{8} ( 1 , i ) & … & {g}_{8} ( \frac{P - 5}{2} , i )\end{matrix} ]$$

$${g}_{i , 9} ( n ) = [ \begin{matrix}{g}_{9} ( 0 , i ) & {g}_{9} ( 1 , i ) & … & {g}_{9} ( \frac{P - 5}{2} , i )\end{matrix} ]$$

In some aspects, the implementation of the BF is simplified by utilizing LUTs in the predistortion block 120. In particular, in some embodiments, as in FIG. 1, the DPD 100 comprises a predistortion block 120 and an adaptation block 180, and coefficients (as part of the complex functions T_{f}) of the basis function are determined and converted into LUTs, in the adaptation block 180. In some aspects, the LUTs are copied into the predistortion block 120. In particular, in some embodiments, the input signal is subjected to the linearization function in the predistortion block 120, and wherein the LUTs are made accessible to, and used by, the predistortion block 120 when subjecting the input signal to the linearization function.

FIG. 4 schematically illustrates an implementation of tap delay i in the predistortion block 120. In the example of FIG. 4, each tap delay contains 9 nonlinear functions, denoted F₁ . . . . F₉, and the implementation of function F₉, and thus LUT_{i,9}, is illustrated. All outputs are added together to generate the output:

$${y}_{i} ( n ) = {\sum }_{f = 1}^{9} {F}_{i , f} ( x ( n ) )$$

Subsequently, the outputs from all tap delays are added together to generate the final output:

$$y ( n ) = {\sum }_{\dot{t} = 0}^{M} {y}_{i} ( n ) .$$

For illustrative purposes, consider function F_{i,9}, i.e., f=9:

$${F}_{i , 9} ( x ( n ) ) = {T}_{9} ( \vert x ( n - {A}_{i} ) \vert ) {x}^{* 2} ( n - {A}_{i} ) {x}^{3} ( n - {D}_{i} )$$

$$where$$

$${T}_{9} ( \vert x ( n - {A}_{i} ) \vert ) = ( {\sum }_{k = 2}^{\frac{P - 1}{2}} {g}_{9} ( k , i ) {\vert x ( n - {A}_{i} ) \vert}^{2 ( k - 2 )} )$$

The summation inside the parentheses can be expressed by a LUT with indexing of |x(n−Aᵢ)|.

Generally, the value of bin l in the LUT for tap delay i and nonlinear function ƒ can be expressed as:

$${LUT}_{i , f} ( l ) = {T}_{f} ( \vert x ( n - {A}_{i} ) \vert )$$

where l is given by a linear mapping function, l=floor (|x(n−Aᵢ)|/R), wherein R denotes the resolution of each bin.

Each of the functions F₁ . . . . F_{f} can be implemented in its own module. This enables each function to be independently activated and deactivated according to the non-linearity of the non-linear electronic device 140. A set of clock gating circuits can be connected to each module. When the non-linearity of the non-linear electronic device 140 is not so strong, just some modules with low-order functions can be activated. Likewise, when non-linearity of the non-linear electronic device 140 is strong, all modules can be activated. This can further reduce the computational complexity and power consumption of the DPD 100.

After the best M tap delays are selected, an adaptation algorithm, as run in the adaptation block 180 can be used to provide the coefficients to be used by the predistortion block 120. In some aspects, a block recursive least squares (block-RLS) algorithm is used to its high performance and fast convergence. That is, in some embodiments, the coefficients of the BF are determined using a block-RLS algorithm. In short, when using the block-RLS algorithm, the coefficient of j:th iteration can be expressed as:

$$g ( j ) = g ( j - 1 ) + P ( j ) {X}_{j}^{H} ( 1 : N , : ) {e}_{j} ( 1 : N )$$

where the gain matrix is given by:

$$P ( j ) = Ψ {( j )}^{- 1} = {( λ {R}_{xx} ( j - 1 ) + {X}_{j}^{H} ( 1 : N , : ) {X}_{j} ( 1 : N , : ) )}^{- 1}$$

$${R}_{xx} ( j ) = {\sum }_{i = 1}^{j} {λ}^{j - i} {X}_{i}^{H} ( 1 : N , : ) {X}_{i} ( 1 : N , : )$$

where λ is a forgetting factor.

That is, in some embodiments, the coefficients are a function of a gain matrix, and determining the gain matrix involves performing a matrix inversion of the matrix Ψ(j).

It could be that Rₓₓ(j) is ill-condition due to high-order polynomials. The inverse of such a matrix inevitably suffers from numerical stability issues. One way to solve this is to impose a regularization term p on the diagonal. In particular, in some embodiments, a regularization term p is added to all diagonal entries of the matrix Ψ(j) before the matrix inversion is performed.

Thus:

$$P ( j ) = {Ψ}^{- 1} = {( λ {R}_{xx} ( j - 1 ) + {X}_{j}^{H} ( 1 : N , : ) {X}_{j} ( 1 : N , : ) + ρ I )}^{- 1} .$$

In some examples, the regularization term p is given by:

$$ρ = max ( diag ( {X}_{j}^{H} ( 1 : N , : ) {X}_{j} ( 1 : N , : ) / {10}^{5}$$

Still, a matrix inversion of Ψ is still needed, yielding a high computational complexity. In some aspects, in order to reduce the computational complexity, simplifications are introduced for the block-RLS algorithm. Examples of such simplifications will be disclosed next.

In some aspects, a new matrix S(n) is defined as:

$$S ( n ) = {( λ {R}_{xx} ( j - 1 ) + {X}_{j}^{H} ( 1 : n , : ) {X}_{j} ( 1 : n , : ) )}^{- 1}$$

It can be seen that S(N)=P(j)=Ψ⁻¹.

Applying the Sherman-Morrison formula, the matrix inversion can be given by

$$S ( n ) = {( {S}^{- 1} ( n - 1 ) + {X}_{j}^{H} ( n , : ) {X}_{j} ( n , : ) )}^{- 1}$$

$$= S ( n - 1 ) - \frac{S ( n - 1 ) {X}_{j}^{H} ( n , : ) {X}_{j} ( n , : ) S ( n - 1 )}{1 + {X}_{j} ( n , : ) S ( n - 1 ) {X}_{j}^{H} ( n , : )}$$

The initial value is already derived in the previous iteration. That is:

$$S ( 0 ) = {λ}^{- 1} {R}_{xx}^{- 1} ( j - 1 ) = {λ}^{- 1} P ( j - 1 )$$

Hence, in some embodiments, the matrix inversion (to obtain P(j)) is recursively performed.

In some aspects only the diagonal entries of the cross-correlation matrix Rₓₓ(j) are used. Then, the matrix inversion can be replaced by vector inversion. The gain matrix is given by

$$P ( j ) = {( λ P {( j - 1 )}^{- 1} + diag ( {X}_{j}^{H} ( 1 : N , : ) {X}_{j} ( 1 : N , : ) ) + ρ I )}^{- 1}$$

Hence, in some embodiments, all but the diagonal entries of the matrix Ψ(j) are set to zero when the matrix inversion is performed.

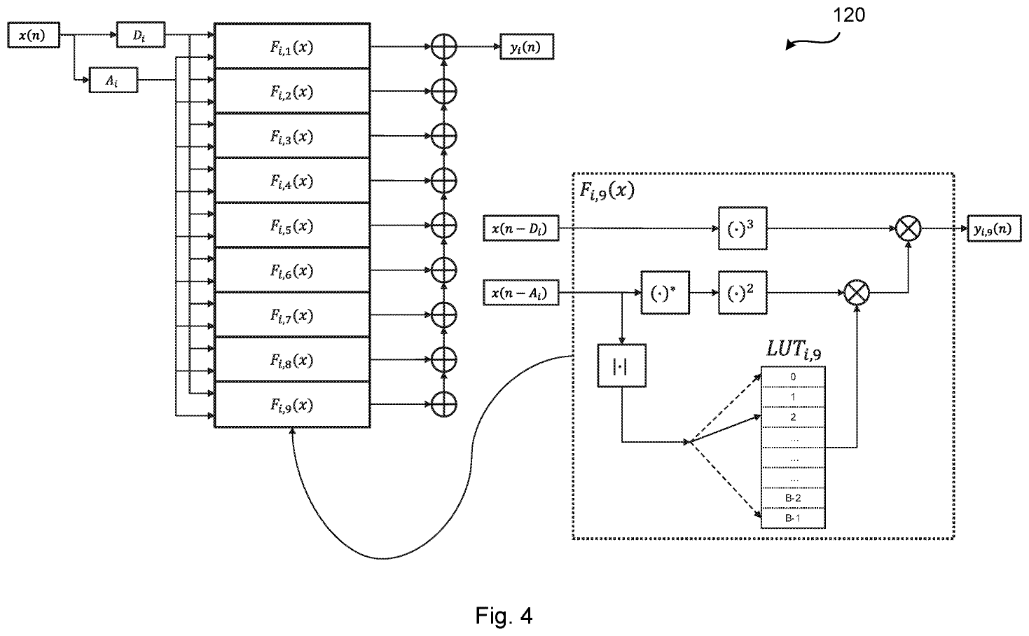

Simulation results will be disclosed next with reference to FIGS. 5, 6, and 7. FIG. 5 shows results for an adjacent channel leakage ratio (ACLR) comparison of a traditional GMP and the proposed DPD considering two 100 MHz carriers with an instantaneous bandwidth (IBW) of 200 MHz. FIG. 6 shows results for an ACLR comparison of a traditional GMP and the proposed DPD considering three 100 MHz carriers with IBW=300 MHz. FIG. 7 shows results for an ACLR comparison of a traditional GMP and the proposed DPD considering two 100 MHz carriers with IBW=400 MHz. The simulation results are shown for a non-linear electronic device 140 in the form of a GaN PA. The PA operates at mid-band spectrum between 3.4 GHz and 3.8 GHz with a nominal average output power of 39 dBm. ACLR measurements are given in Table 2 (where “w/o DPD” means “without DPD”). The sampling frequency of the input signal was set to 983.04 MHZ. A 700 MHz band-limited filter was inserted into the feedback path to yield a 700 MHz linearization bandwidth.

TABLE 2
Measurements of three test cases

| | TC1 (2 × 100 MHz, | | TC2 (3 × 100 MHz, | | TC3 (2 × 100 MHz, | |
|---|---|---|---|---|---|---|
| | 200 MHz IBW) | | 300 MHz IBW) | | 400 MHz IBW) | |
| ACLR (dBc) | Left side | Right side | Left side | Right side | Left side | Right side |
| w/o DPD | −29.90 | −29.07 | −29.30 | −28.82 | −34.63 | −32.37 |
| GMP based | −42.09 | −41.44 | −40.69 | −39.87 | −41.08 | −43.15 |
| DPD | | | | | | |
| Proposed | −48.25 | −47.62 | −46.73 | −45.90 | −48.70 | −47.28 |
| DPD | | | | | | |

In Test Case 1 (TC1), an orthogonal frequency-division multiplexing (OFDM) signal with two 100 MHz carriers were considered for the evaluation. Two carriers are allocated tightly between each other, and therefore the IBW equals to 200 MHz. It can be seen that the proposed DPD outperforms the GMP based DPD with approximately 6.2 dB in terms of ACLR. In Test Case 2 (TC2), three 100 MHz carriers with IBW=300 MHz were considered. The result also shows that the proposed DPD gives approximately 6.0 dB performance improvement over the GMP based DPD. In Test Case 3 (TC3), two 100 MHz carriers were considered with 300 MHz space between the carrier centers that leads to IBW=400 MHZ. From the obtained results, it can be observed that the proposed DPD achieves approximately 7.6 dB and 4.1 dB performance improvements at the lower frequency side and the upper frequency side, respectively. One reason for this performance difference is that the linearization of higher frequencies is comparatively more difficult than that of lower frequencies. It can also be observed that the skirt around the carriers almost disappeared in all test cases. This confirms the outstanding performance of the proposed DPD thanks to the powerful BF and adaptation.

In summary, in this disclosure has been proposed a DPD yielding excellent performance with relatively low computational complexity.

The DPD is based on a powerful BF that is pruned from VS. Terms are included in the BF to handle high order distortions. Common tap delays can be shared by all polynomial terms, which can simplify the implementation without degradation in the performance. Test results confirm that the DPD gives comparable performance in terms of ACLR against state-of-the-art DPDs.

A mixture model of polynomials and LUTs can be used for implementation. The coefficients of the polynomials are calculated and converted into LUTs in the adaptation block, and copied from there into the predistortion block. In this way, heavy computations can be avoided.

A simplified block-RLS algorithm, yielding similar results compared to conventional RLS algorithms but with lower computational complexity. A regularization term might be added to avoid instability in the case the BF is ill-conditioned. The converging rate is fast enough to track the dynamic behavior with small performance degradation. Test results confirm that the proposed adaptation is competent for the proposed BF in different carrier configurations.

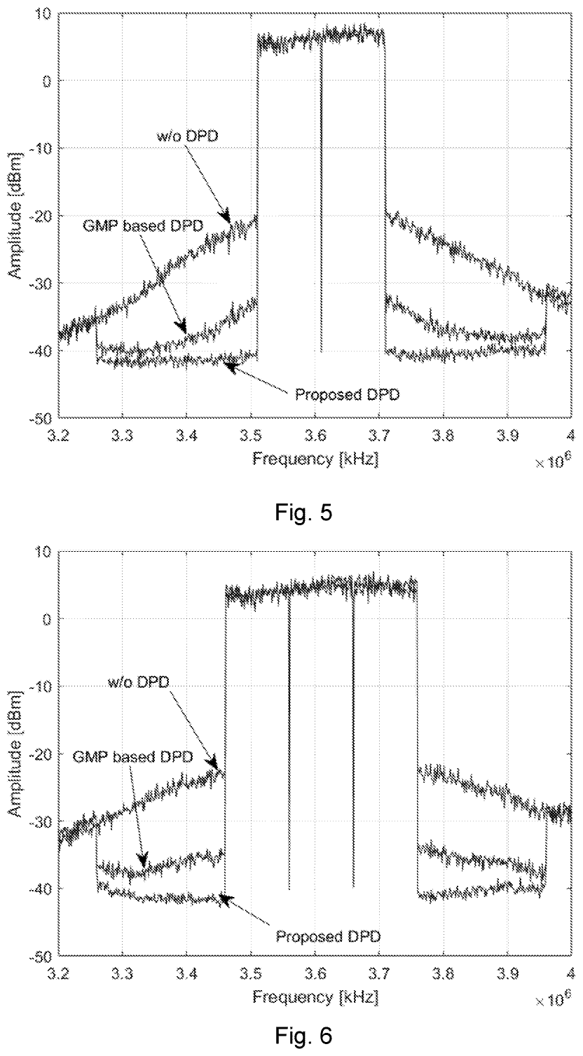

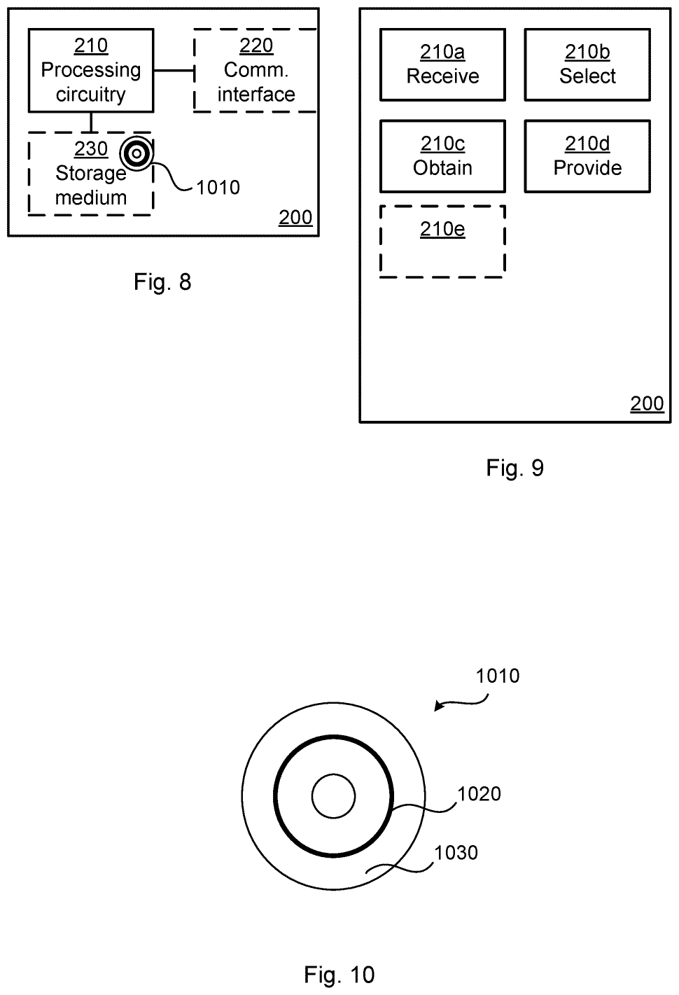

FIG. 8 schematically illustrates, in terms of a number of functional units, the components of a DPD controller 200 according to an embodiment. Processing circuitry 210 is provided using any combination of one or more of a suitable central processing unit (CPU), multiprocessor, microcontroller, digital signal processor (DSP), etc., capable of executing software instructions stored in a computer program product 1010 (as in FIG. 10), e.g. in the form of a storage medium 230. The processing circuitry 210 may further be provided as at least one application specific integrated circuit (ASIC), or field programmable gate array (FPGA).

Particularly, the processing circuitry 210 is configured to cause the DPD controller 200 to perform a set of operations, or steps, as disclosed above. For example, the storage medium 230 may store the set of operations, and the processing circuitry 210 may be configured to retrieve the set of operations from the storage medium 230 to cause the DPD controller 200 to perform the set of operations. The set of operations may be provided as a set of executable instructions.

Thus the processing circuitry 210 is thereby arranged to execute methods as herein disclosed. The storage medium 230 may also comprise persistent storage, which, for example, can be any single one or combination of magnetic memory, optical memory, solid state memory or even remotely mounted memory. The DPD controller 200 may further comprise a communications interface 220 at least configured for communications with other entities, functions, nodes, and devices. As such the communications interface 220 may comprise one or more transmitters and receivers, comprising analogue and digital components. The processing circuitry 210 controls the general operation of the DPD controller 200 e.g. by sending data and control signals to the communications interface 220 and the storage medium 230, by receiving data and reports from the communications interface 220, and by retrieving data and instructions from the storage medium 230. Other components, as well as the related functionality, of the DPD controller 200 are omitted in order not to obscure the concepts presented herein.

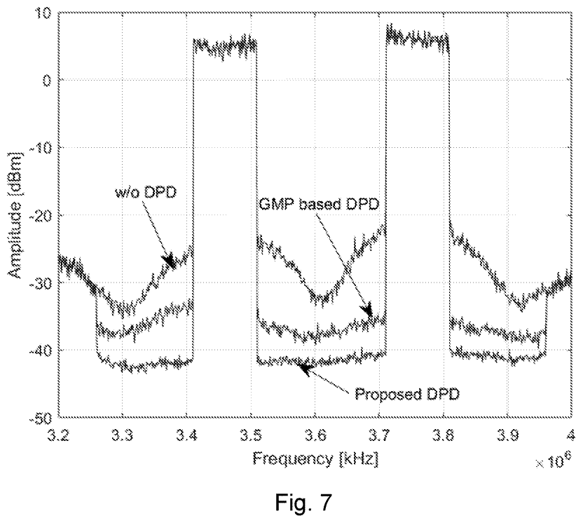

FIG. 9 schematically illustrates, in terms of a number of functional modules, the components of a DPD controller 200 according to an embodiment. The DPD 200 of FIG. 8 comprises a number of functional modules; a receive module 210a configured to perform step S102, a select module 210b configured to perform step S104, an obtain module 210c configured to perform step S106, and a provide module 210d configured to perform step S108. The DPD 200 of FIG. 8 may further comprise a number of optional functional modules, as represented by functional module 210e. In general terms, each functional module 210a: 210e may in one embodiment be implemented only in hardware and in another embodiment with the help of software, i.e., the latter embodiment having computer program instructions stored on the storage medium 230 which when run on the processing circuitry makes the DPD controller 200 perform the corresponding steps mentioned above in conjunction with FIG. 9. It should also be mentioned that even though the modules correspond to parts of a computer program, they do not need to be separate modules therein, but the way in which they are implemented in software is dependent on the programming language used. Preferably, one or more or all functional modules 210a: 210e may be implemented by the processing circuitry 210, possibly in cooperation with the communications interface 220 and/or the storage medium 230. The processing circuitry 210 may thus be configured to from the storage medium 230 fetch instructions as provided by a functional module 210a: 210e and to execute these instructions, thereby performing any steps as disclosed herein.

The DPD controller 200 may be provided as a standalone device or as a part of at least one further device. For example, the functionality of the DPD controller 200 may collocated with the functionality of the non-linear electronic device 140. A first portion of the instructions performed by the DPD controller 200 may be executed in a first device, and a second portion of the of the instructions performed by the DPD controller 200 may be executed in a second device; the herein disclosed embodiments are not limited to any particular number of devices on which the instructions performed by the DPD controller 200 may be executed.

FIG. 10 shows one example of a computer program product 1010 comprising computer readable storage medium 1030. On this computer readable storage medium 1030, a computer program 1020 can be stored, which computer program 1020 can cause the processing circuitry 210 and thereto operatively coupled entities and devices, such as the communications interface 220 and the storage medium 230, to execute methods according to embodiments described herein. The computer program 1020 and/or computer program product 1010 may thus provide means for performing any steps as herein disclosed.

In the example of FIG. 10, the computer program product 1010 is illustrated as an optical disc, such as a CD (compact disc) or a DVD (digital versatile disc) or a Blu-Ray disc. The computer program product 1010 could also be embodied as a memory, such as a random access memory (RAM), a read-only memory (ROM), an erasable programmable read-only memory (EPROM), or an electrically erasable programmable read-only memory (EEPROM) and more particularly as a non-volatile storage medium of a device in an external memory such as a USB (Universal Serial Bus) memory or a Flash memory, such as a compact Flash memory. Thus, while the computer program 1020 is here schematically shown as a track on the depicted optical disk, the computer program 1020 can be stored in any way which is suitable for the computer program product 1010.

The inventive concept has mainly been described above with reference to a few embodiments. However, as is readily appreciated by a person skilled in the art, other embodiments than the ones disclosed above are equally possible within the scope of the inventive concept, as defined by the appended patent claims.

1. A method for operating a digital pre-distorter, DPD, (100) for a non-linear electronic device (140), the method being performed by a DPD controller (200), the method comprising:
receiving (S102) an input signal destined to be input to the non-linear electronic device (140);
selecting (S104) a basis function, BF, that represent non-linear input-output characteristics of the non-linear electronic device (140), wherein the basis function is defined by kernels of a pruned Volterra series, VS, and comprises higher-than-order-1 polynomial terms, polynomial cross-terms, memory cross-terms, and common tap delays shared by all polynomial terms;
obtaining (S106) an output signal by subjecting the input signal to a linearization function defined by the basis function; and
providing (S108) the output signal as input to the non-linear electronic device (140).

2. The method according to claim 1, wherein polynomial orders of the higher-than-order-1 polynomial terms depend on statistics of the input signal and/or the non-linear input-output characteristics of the non-linear electronic device (140).

3. The method according to claim 1, wherein the tap delays are selected using a block orthogonal matching pursuit, block-OMP, algorithm.

4. The method according to claim 3, wherein the tap delays are selected from a set of available candidate tap delays.

5. The method according to claim 4, wherein the set of available candidate tap delays is represented by a matrix, and wherein the selected tap delays represent a submatrix extracted from the matrix.

6. The method according to claim 1, wherein for a memory length M, the basis function is defined by:
$$y ( n ) = {\sum }_{i = 0}^{M} {\sum }_{f} {y}_{i , f} ( n ) , where :$$
$${y}_{i , f} ( n ) = {T}_{f} ( \vert x ( n - {A}_{i} ) \vert ) {x}^{* {q}_{2}} ( n - {A}_{i} ) {x}^{{p}_{2}} ( n - {A}_{i} ) {x}^{* {q}_{1}} ( n - {D}_{i} ) {x}^{{p}_{1}} ( n - {D}_{i} ) ,$$
where x(n) denotes the input signal, where y(n) denotes the output signal, where Aᵢ denotes address delay for filter tap i, where Dᵢ denotes data delay for the filter tap i, where q₁, q₂, p₁, and p₂ denote polynomial orders, where T_{f}(|x(n−Aᵢ)|) represents the f:th complex function with respect to |x(n−Aᵢ)|, and where x* denotes complex conjugate of x.

7. The method according to claim 1, wherein the DPD (100) comprises a predistortion block (120) and an adaptation block (180), and wherein coefficients of the basis function are determined and converted into look-up tables, LUTs, in the adaptation block (180).

8. The method according to claim 7, wherein the input signal is subjected to the linearization function in the predistortion block (120), and wherein the LUTs are made accessible to, and used by, the predistortion block (120) when subjecting the input signal to the linearization function.

9. The method according to claim 7, wherein the value of bin l in the LUT for tap delay i and nonlinear function f is given by:
$${LUT}_{i , f} ( l ) = {T}_{f} ( \vert x ( n - {A}_{i} ) \vert )$$
where l is given by a linear mapping function, l=floor (|x(n−Aᵢ|/R), wherein R denotes resolution of each bin.

10. The method according to claim 1, wherein coefficients of the basis function are determined using a block recursive least squares, block-RLS, algorithm.

11. The method according to claim 10, wherein the coefficients are a function of a gain matrix, and wherein determining the gain matrix involves performing a matrix inversion of a matrix Ψ.

12. The method according to claim 10, wherein a regularization term is added to all diagonal entries of the matrix Ψ before the matrix inversion is performed.

13. The method according to claim 10, wherein the matrix inversion is recursively performed.

14. The method according to claim 10, wherein all but the diagonal entries of the matrix Ψ are set to zero when the matrix inversion is performed.

15. A digital pre-distorter, DPD, controller (200) for operating a DPD (100) for a non-linear electronic device (140), the DPD controller (200) comprising processing circuitry (210), the processing circuitry being configured to cause the DPD controller (200) to:
receive an input signal destined to be input to the non-linear electronic device (140);
select a basis function, BF, that represent non-linear input-output characteristics of the non-linear electronic device (140), wherein the basis function is defined by kernels of a pruned Volterra series, VS, and comprises higher-than-order-1 polynomial terms, polynomial cross-terms, memory cross-terms, and common tap delays shared by all polynomial terms;
obtain an output signal by subjecting the input signal to a linearization function defined by the basis function; and
provide the output signal as input to the non-linear electronic device (140).

16. The DPD controller of claim 15, further comprising:
a receive module (210a) configured to perform the step of receiving the input signal destined to be input to the non-linear electronic device (140);
a select module (210b) configured to perform the step of selecting the BF;
an obtain module (210c) configured to perform the step of obtaining the output signal by subjecting the input signal to a linearization function defined by the basis function; and
a provide module (210d) configured to perform the step of providing the output signal as input to the non-linear electronic device (140).

17. The DPD controller (200) according to claim 15, wherein polynomial orders of the higher-than-order-1 polynomial terms depend on statistics of the input signal and/or the non-linear input-output characteristics of the non-linear electronic device (140).

18. A computer program (1020) for operating a digital pre-distorter, DPD, (100) for a non-linear electronic device (140), the computer program comprising computer code which, when run on processing circuitry (210) of a DPD controller (200), causes the DPD controller (200) to:
receive (S102) an input signal destined to be input to the non-linear electronic device (140);
select (S104) a basis function, BF, that represent non-linear input-output characteristics of the non-linear electronic device (140), wherein the basis function is defined by kernels of a pruned Volterra series, VS, and comprises higher-than-order-1 polynomial terms, polynomial cross-terms, memory cross-terms, and common tap delays shared by all polynomial terms;
obtain (S106) an output signal by subjecting the input signal to a linearization function defined by the basis function; and
provide (S108) the output signal as input to the non-linear electronic device (140).

19. A computer program product (1010) comprising a computer program (1020) according to claim 18, and a computer readable storage medium (1030) on which the computer program is stored.
